(19) United States
(12) Patent Application Publication
(10) Pub. No.: US 2011/0234311 A1
(43) Pub. Date: Sep. 29, 2011

(54) CURRENT DETECTION CIRCUIT AND INFORMATION TERMINAL

(75) Inventors: Kenichi Hirashiki, Yokohama-shi (JP); Minoru Nagata, Yokohama-shi (JP)

(73) Assignee: KABUSHIKI KAISHA TOSHIBA, Tokyo (JP)

(21) Appl. No.: 13/047,000

(22) Filed: Mar. 14, 2011

(30) Foreign Application Priority Data
Mar. 25, 2010 (JP) 2010-70601
Mar. 25, 2010 (JP) 2010-70617

(51) Int. Cl. H03H 11/00

(52) U.S. Cl. 327/581

(57) ABSTRACT

According to one embodiment, a current detection circuit is provided with: a NMOS transistor, whose control signal is given to a gate electrode, whose source electrode is connected to a ground line, and whose drain electrode is connected to an input/output terminal; a first PMOS transistor, in which the control signal is given to a gate electrode, and whose drain electrode is connected to the input/output terminal and the drain electrode of the NMOS transistor; and a second PMOS transistor, whose drain electrode is connected to the source electrode of the first PMOS transistor, and a first supply voltage is given to a source electrode. A detection section detects whether or not a current has changed at the input/output terminal from a change in current flowing through the second PMOS transistor.

### CROSS REFERENCE TO RELATED APPLICATION

This application is based upon and claims benefit of priority from the Japanese Patent Application No. 2010-70601, filed on Mar. 25, 2010, and the Japanese Patent Application No. 2010-70617, filed on Mar. 25, 2010, the entire contents of all of which are incorporated herein by reference.

### FIELD

Embodiments described herein relate generally to a current detection circuit and an information terminal.

### BACKGROUND

There is known an apparatus provided with a current detection circuit that outputs a predetermined voltage to another circuit through one wire to transmit data, while detecting a change in current flowing along this wire to obtain data from another circuit (e.g., see Japanese Patent Application Laid-Open No. 2009-253986). This current detection circuit is, for example, provided in a mobile phone, and obtains information on a subscriber which is required for a conversation through one wire from an IC card inserted into the mobile phone. The subscriber information, for example, includes data concerning a subscriber oneself and information on a subscribed communication carrier and a phone number.

In order to detect a change in current in this wire, for example, a technique is known in which resistors are connected in series or a current mirror circuit is provided between an input/output terminal (wire) and a supply voltage line.

However, when the resistors are connected in series, it leads to a problem of variations in output voltages toward another circuit. Further, when the current mirror is provided, it leads to a problem of occurrence of a voltage drop due to a PMOS transistor constituting the current mirror circuit, thus decreasing the output voltage and making it impossible to output a desired voltage.

Moreover, a parasitic capacity is generated at the input/output terminal, and when the output voltage becomes high, the current is extracted for charging of the parasitic capacity. A conventional circuit has had a problem of being unable to determine whether this extraction of the current is attributed to another circuit or to the charged current of the parasitic capacity.

### BRIEF DESCRIPTION OF THE DRAWINGS

FIG. 1 is a view showing a schematic configuration of a current detection circuit according to a first embodiment of the present invention;

FIG. 2 is a view showing a schematic example of a circuit configuration of the current detection circuit according to the first embodiment;

FIG. 3 is a view showing an information terminal provided with the current detection circuit, and an IC card into which data is read from this information terminal;

FIG. 4 is a view showing a schematic configuration of a current detection circuit according to a second embodiment of the present invention;

FIG. 5 is a view showing a schematic configuration of a current detection circuit according to a third embodiment of the present invention;

FIG. 6 is a view showing a schematic configuration of a current detection circuit according to a modification; and

FIG. 7 is a view showing a schematic configuration of a current detection circuit according to a modification.

### DETAILED DESCRIPTION

According to one embodiment, a current detection circuit is provided with: a NMOS transistor, whose control signal is given to a gate electrode, whose source electrode is connected to a ground line, and whose drain electrode is connected to an input/output terminal; a first PMOS transistor, in which the control signal is given to a gate electrode, and whose drain electrode is connected to the input/output terminal and the drain electrode of the NMOS transistor; and a second PMOS transistor, whose drain electrode is connected to the source electrode of the first PMOS transistor, and a first supply voltage is given to a source electrode. A detection section detects whether or not a current has changed at the input/output terminal from a change in current flowing through the second PMOS transistor.

Hereinafter, embodiments of the present invention are described based on the drawings.

### First Embodiment

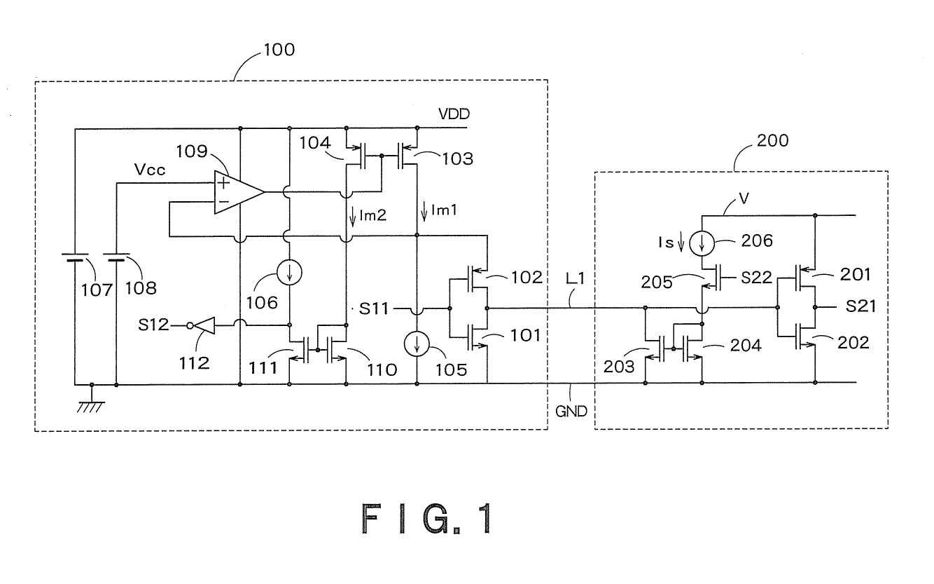

FIG. 1 shows a schematic configuration of a current detection circuit 100 according to an embodiment of the present invention. The current detection circuit 100 outputs a voltage to a device 200 through one input/output line L1 and a ground line GND, while detecting a current change at an input/output terminal (connection terminal with the device 200).

The current detection circuit 100 switches between high/low levels of a voltage which is output through the input/output line L1. The current at the input/output terminal of the current detection circuit 100 changes depending upon whether or not the device 200 extracts a current flowing along the input/output line L1. The device 200 can extract the current flowing along the input/output line L1 at a desired moment during a period when a voltage value of the output voltage from the current detection circuit 100 is high.

The current detection circuit 100 is provided with NMOS transistors 101, 110, 111, PMOS transistors 102 to 104, current sources 105, 106, voltage sources 107, 108, an operational amplifier 109, and an inverter 112. A source electrode of the NMOS transistor 101 is connected to the ground line GND, and a drain electrode thereof is connected to a drain electrode of the PMOS transistor 102 and the input/output line L1. That is, the drain electrode of the NMOS transistor 101 and the drain electrode of the PMOS transistor 102 are connected to the input/output terminal of the current detection circuit 100.

A gate electrode of the NMOS transistor 101 is connected to a gate electrode of the PMOS transistor 102, and is given a signal (control signal) S11.

A source electrode of the PMOS transistor 102 is connected to a drain electrode of the PMOS transistor 103 and an inverting input terminal of the operational amplifier 109. A noninverting input terminal of the operational amplifier 109 is given a voltage Vcc by the voltage source 108. An output terminal of the operational amplifier 109 is connected to a gate electrode of the PMOS transistor 103 and a gate electrode of the PMOS transistor 104.

The PMOS transistors 103, 104 are given a voltage VDD by the voltage source 107. The current source 105 is provided between the drain electrode of the PMOS transistor 103 and the ground line GND, and a drain voltage of the PMOS transistor 103 is held constant. Further, the NMOS transistor 110 is provided between a drain electrode of the PMOS transistor 104 and the ground line GND. The PMOS transistor 103 is a transistor larger in size than the PMOS transistor 104, and a size ratio is, for example, 10:1.

The drain electrode of the PMOS transistor 104 is connected to a drain electrode and a gate electrode of the NMOS transistor 110, and a gate electrode of the NMOS transistor 111. Source electrodes of the NMOS transistors 110, 111 are connected to the ground line GND, and a drain electrode of the NMOS transistor 111 is connected to the current source 106 and an input terminal of the inverter 112.

Next, the device 200 is described. The device 200 has a PMOS transistor 201, NMOS transistors 202 to 205, and a current source 206. A source electrode of the NMOS transistor 202 is connected to the ground line GND, and a drain electrode thereof is connected to a drain electrode of the PMOS transistor 201. A gate electrode of the NMOS transistor 202 is connected to a gate electrode of the PMOS transistor 201 and the input/output line L1. A Drain voltage of each of the NMOS transistor 202 and the PMOS transistor 201 becomes a signal S21.

The current source 206 is provided between a drain electrode of the NMOS transistor 205 and a voltage line V. A signal S22 of the device 200 is given to a gate electrode of the NMOS transistor 205, and a source electrode thereof is connected to a drain electrode and a gate electrode of the NMOS transistor 204 and a gate electrode of the NMOS transistor 203. A source electrode of the NMOS transistor 204 is connected to the ground line GND. A drain electrode of the NMOS transistor 203 is connected to the input/output line L1, and a source electrode thereof is connected to the ground line GND. The NMOS transistor 203 is a transistor larger in size than the NMOS transistor 204, and a size ratio is, for example, 75:1.

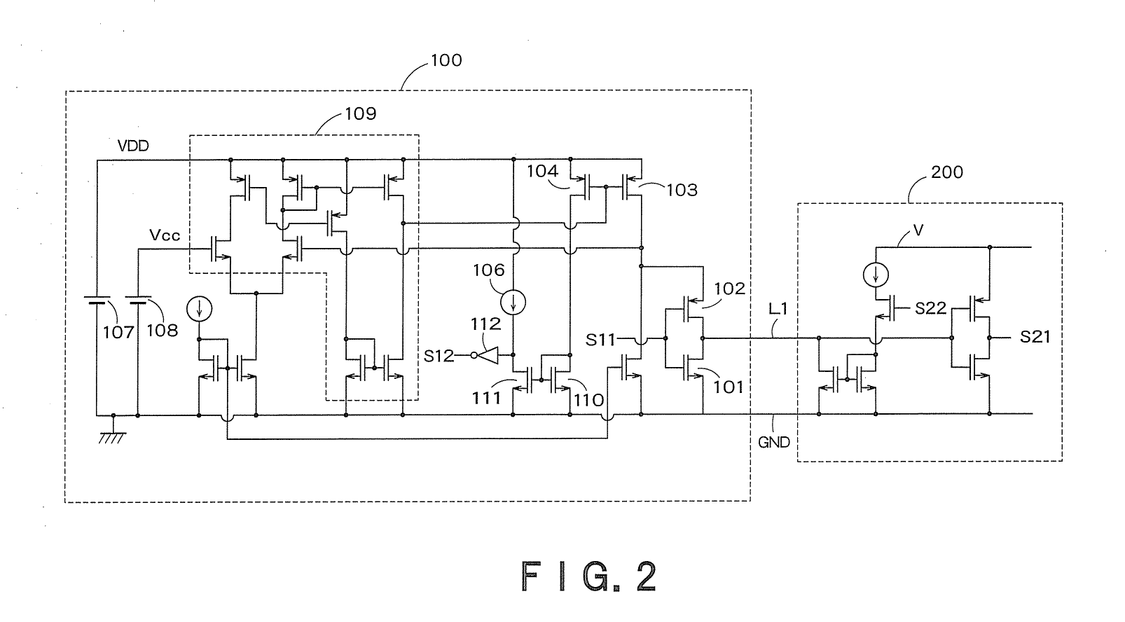

A specific circuit example of the current detection circuit 100 is a configuration as shown in FIG. 2.

Subsequently, a description is given to switching of the output voltage by the current detection circuit 100 and detection of the current change at the input/output terminal.

When the signal (control signal) S11 of the current detection circuit 100 is on high level, the PMOS transistor 102 is turned off, the NMOS transistor 101 is turned on, and a voltage value of the input/output line L1 shifts to a low level. On the other hand, when the signal S11 is on low level, the PMOS transistor 102 is turned on, the NMOS transistor 101 is turned off, and the voltage value of the input/output line L1 shifts to a high level. With the voltage value of the input/output line L1 switched, the signal S21 is switched in the device 200.

When the signal S22 of the device 200 is on high level, the NMOS transistor 205 is turned on. The NMOS transistor 203 is then turned on, and the current flowing along the input/output line L1 is extracted. The extraction of the current in the input/output line L1 can be performed only at the time of the output voltage of the current detection circuit 100 being on high level.

The current extracted from the input/output line L1 is determined based on a current Is, which is allowed to flow by the current source 206, and the size ratio between the NMOS transistors 203, 204. For example, in the case of the size ratio between the NMOS transistors 203, 204 is 75:1, the current extracted from the input/output line L1 is 75 times as large as the current Is.

When the current in the input/output line L1 is extracted, a current value of a current Im1 flowing through the PMOS transistor 103 changes. The current Im1 makes a quick change due to the current source 105. Associated with the change in current Im1, a current value of a current Im2 flowing through the PMOS transistor 104 also changes. The current values of the current Im1 and the current Im2 are determined based on the size ratio between the PMOS transistors 103, 104. For example, in the case of the size ratio between the PMOS transistors 103, 104 is 10:1, the current Im2 is a tenth as large as the current Im1.

With the change in current Im2, a current flowing through the drain electrode of the NMOS transistor 111 changes. A drain voltage of the NMOS transistor 111 changes in a case where the current Im2 is larger, or smaller, than a current allowed to flow by the current source 106. This change in drain voltage is detected from an output of the inverter 112, to obtain a signal S12. In such a manner, the signal S12 is obtained which indicates whether or not the current in the input/output line L1 has been extracted.

The current detection circuit 100 takes a voltage source (PMOS transistors 103, 104) for an output voltage from the input/output line L1 as a regulator provided with a (current monitor) function for detecting a current change. With the PMOS transistor 103 not constituting a current mirror circuit, a voltage drop does not occur, and a decrease in output voltage from the current detection circuit 100 can be prevented.

Further, since the PMOS transistor 102 corresponding to the connecting section with the device 200 is not connected with a resistor, it is possible to prevent variations in output voltage from the current detection circuit 100, so as to accurately determine an output voltage.

As thus described, according to the present embodiment, the current detection circuit 100 is capable of preventing a decrease and variations in output voltage, so as to accurately detect a current change at the input/output terminal.

The transistor, included in the current detection circuit 100 according to the above embodiment, may be configured with its polarities made opposite.

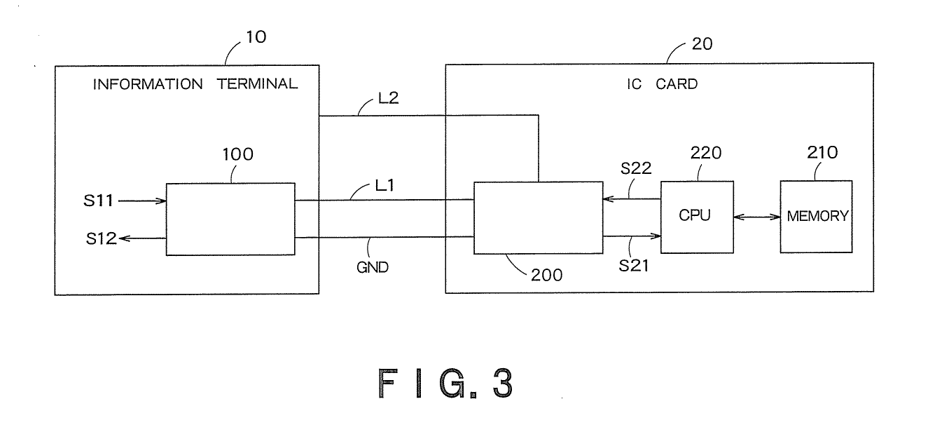

As shown in FIG. 3, providing the current detection circuit 100 according to the above embodiment in an information terminal 10 such as a mobile phone enables transmission and reception of data to and from an IC card 20 provided with the device 200.

The information terminal 10 transmits and receives data to and from the IC card 20 through the input/output line L1. Further, the information terminal 10 supplies a power supply to the device 200 of the IC card 20 through a line L2.

The IC card 20 has a device 200, a memory 210 and a CPU 220. Various pieces of data are stored in the memory 210. For example, when the information terminal 10 is a mobile phone, the memory 210 stores data on a user oneself who uses the mobile phone, information on a subscribed communication carrier and a phone number, and the like.

Based on the signal S21 output from the device 200, the CPU 220 obtains data output from the information terminal 10, and reads and writes data from and into the memory 210.

Further, the CPU 220 can output the signal S22 to the device 200, to switch on/off the NMOS transistor 205 so as to transmit data to the information terminal 10 based on whether or not to extract the current flowing along the input/output line L1. In this manner, the CPU 220 can transmit data, read from the memory 210, to the information terminal 10.

As described above, the current detection circuit 100 is capable of accurately detecting a current change in the input/output line L1. Based on the signal S12 indicating whether or not the current in the input/output line L1 has been extracted, the information terminal 10 obtains data from the IC card 20, and performs communication by means of this data.

### Second Embodiment

FIG. 3 shows a schematic configuration of a current detection circuit 300 according to a second embodiment of the present invention. As does the current detection circuit 100 according to the first embodiment shown in FIG. 1, the current detection circuit 300 outputs a voltage to the device 200 through one input/output line L1 and the ground line GND, while detecting a current change at the input/output terminal (connection terminal with the device 200).

The current detection circuit 300 switches between high/low levels of a voltage which is output through the input/output line L1. The current at the input/output terminal of the current detection circuit 300 changes depending upon whether or not the device 200 extracts a current flowing along the input/output line L1. The device 200 can extract the current flowing along the input/output line L1 at a desired moment during a period when a voltage value of the output voltage from the current detection circuit 300 is high.

When a parasitic capacity C1 is generated at the input/output terminal (input/output line L1) of the current detection circuit 300 and the output voltage of the current detection circuit 300 becomes high, the current is extracted for charging of the parasitic capacity C1. The current detection circuit 300 according to the present embodiment is to prevent the extraction of the current associated with charging of the parasitic capacity C1 from being erroneously detected as extraction of the current by the device 200.

A description is given to the current detection circuit 300. A source electrode of a NMOS transistor 301 is connected to the ground line GND, and a drain electrode thereof is connected to a drain electrode of the PMOS transistor 302 and the input/output line L1. That is, the drain electrode of the NMOS transistor 301 and the drain electrode of the PMOS transistor 302 are connected to the input/output terminal of the current detection circuit 300.

A gate electrode of the NMOS transistor 301 is connected to a gate electrode of the PMOS transistor 302, and is given the signal (control signal) S11.

A source electrode of the PMOS transistor 302 is connected to a drain electrode of the PMOS transistor 303, a drain electrode of a NMOS transistor 310, and one ends of capacitors 321, 322 and resistors 323, 325. The other end of the capacitor 321 is connected to the ground line GND. The source electrode of the PMOS transistor 302 is held constant due to the PMOS transistor 303.

The other ends of the capacitor 322 and the resistor 323 are connected to a gate electrode of a NMOS transistor 305 and one end of a resistor 324. The other end of the resistor 324 is connected to the ground line GND.

NMOS transistors 304, 305, and PMOS transistors 306, 307 constitute a differential input stage of an operational amplifier, and a NMOS transistor 308 becomes a current source thereof. A gate electrode of the NMOS transistor 304 is given a voltage Vref by a power source 331. Therefore, the voltage Vref and a voltage at a connection point of the resistor 323 and the resistor 324 become inputs of the operational amplifier. An output signal of this operational amplifier (differential input stage) is given to a gate electrode of the PMOS transistor 303 and a gate electrode of a PMOS transistor 311. Further, this output signal is given to the other end of the resistor 325 through a capacitor 326.

A current source 341 is connected to gate electrodes of the NMOS transistors 308 to 310 and a drain electrode of the NMOS transistor 309. Source electrodes of the NMOS transistors 308 to 310 are connected to the ground line GND.

Source electrodes of the PMOS transistors 303, 306, 307, 311 are applied with the voltage VDD by a power supply 332.

A drain electrode of the PMOS transistor 311 is connected to a drain electrode and a gate electrode of a NMOS transistor 312 and a gate electrode of a NMOS transistor 313. Source electrodes of the NMOS transistor 312, 313 are connected to the ground line GND, and a drain electrode of the NMOS transistor 313 is connected to a current source 342 and an input terminal of an inverter 350. The PMOS transistor 311, the NMOS transistors 312, 313 and the current source 342 constitute a current monitor circuit for monitoring a current Im3 which is allowed to flow by the current source 342 through the PMOS transistor 303.

Further, a replica capacity 327 is provided between the drain electrode of the PMOS transistor 311 and the ground line GND.

The device 200 has a similar configuration to that in the above first embodiment, and a description thereof will not be repeated.

Subsequently, a description is given to an operation of the current detection circuit 300.

When the signal (control signal) S11 of the current detection circuit 300 is on high level, the PMOS transistor 302 is turned off, the NMOS transistor 301 is turned on, and a voltage value of the input/output line L1 shifts to a low level. On the other hand, when the signal S11 is on low level, the PMOS transistor 302 is turned on, the NMOS transistor 301 is turned off, and the voltage value of the input/output line L1 shifts to a high level. In such a manner, the current detection circuit 300 switches the two values of high/low levels of the voltage which is output through the input/output line L1.

When the current of the input/output line L1 is extracted, a current value of the current Im3 flowing through the PMOS transistor 303 changes, and a current (monitor current) Im4 flowing through the PMOS transistor 311 increases. With the increase in current Im4, the replica capacity 327 is charged. Upon completion of charging of the replica capacity 327, a current flows through the drain electrode of the NMOS transistor 313, and a current comparison between the monitor current and a reference current which is allowed to flow by the current source 342 is performed.

A drain voltage of the NMOS transistor 313 changes in a case where this monitor current is larger, or smaller, than the reference current. This change in drain voltage is detected from an output of the inverter 350, to obtain the signal S12. In such a manner, the signal S12 is obtained which indicates whether or not the current in the input/output line L1 has been extracted.

When the extraction of the current in the input/output line L1 is for charging of the parasitic capacity C1, since the time when the current is being extracted is extremely short, the time when the monitor current Im4 takes a large value is also extremely short. Accordingly, the current extraction associated with charging of the parasitic capacity C1 is completed during charging of the replica capacity 327, thus enabling the current detection circuit 300 to prevent erroneous detection that the current has been extracted by the device 200.

As thus described, according to the current detection circuit according to the present embodiment, the replica capacity 327 is provided in the current monitor circuit for performing a comparison between the monitor current and the reference current, and the current comparison is kept from being performed until completion of charging of the replica capacity 327 by the monitor current, whereby it is possible to cancel detection of the current change (current extraction) due to a charged current of the parasitic capacity.

### Third Embodiment

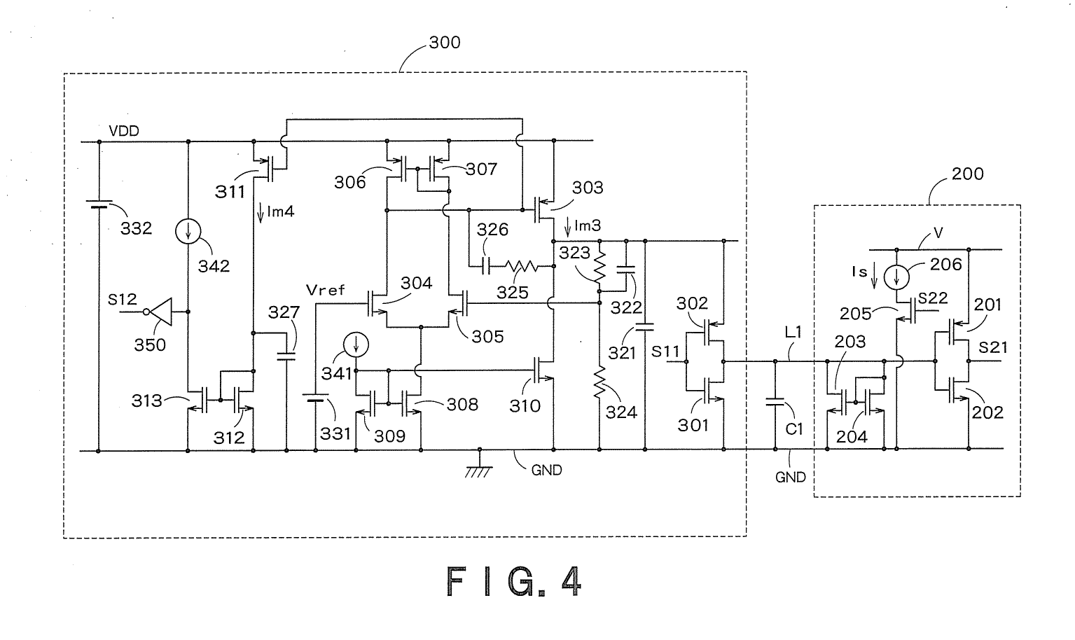

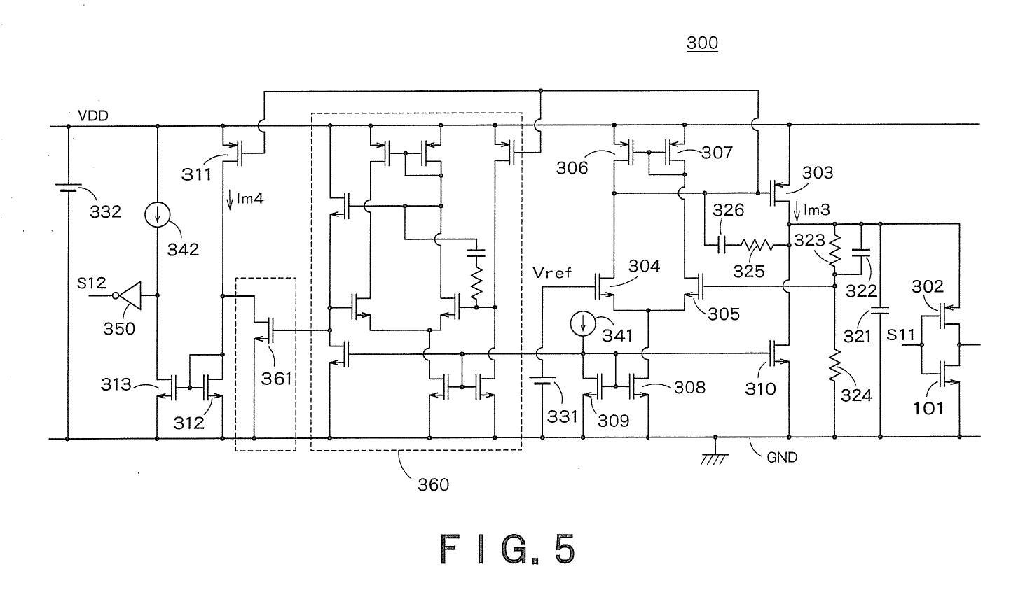

FIG. 5 shows a schematic configuration of a current detection circuit according to a third embodiment of the present invention. As compared with the above second embodiment shown in FIG. 4, the present embodiment is different in that the replica capacity 327 is omitted and a current change detecting section 360 and a NMOS transistor 361 are provided. In FIG. 5, the same components are denoted by the same reference numerals as those in the second embodiment as shown in FIG. 4, and description thereof will not be repeated.

The current change detecting section 360 includes a differentiation circuit, and a change in current Im3 is detected by the differentiation circuit, a result of which is then output to the NMOS transistor 361.

A drain electrode of the NMOS transistor 361 is connected to the drain electrode of the PMOS transistor 311, a source electrode thereof is connected to the ground line GND, and a gate electrode thereof is given a result of detection by the current change detecting section 360. The NMOS transistor 361 is turned on when the current change detecting section 360 detects a current change. During the on-time of the NMOS transistor 361, a current flowing through the NMOS transistor 361 is deducted from the monitor current Im4. Therefore, a value of the monitor current, subjected to the current comparison with the reference current, is reduced and the detection of the current change can be cancelled during the on-time of the NMOS transistor 361.

The time when the monitor current Im4 takes a large value due to charging of the parasitic capacity C1 is extremely short. Therefore, by the current change detecting section 360 detecting the current change due to charging of the parasitic capacity C1 to turn on the NMOS transistor 361, the monitor current Im4 is deducted (part of the monitor current Im4 is guided to the ground line GND), and an output value of the inverter 350 remains unchanged. This enables the current detection circuit 300 to prevent erroneous detection that the current has been extracted by the device 200.

As thus described, in the current detection circuit according to the present embodiment, with attention paid upon that the charged current of the parasitic capacity C1 has a large inclination with respect to a temporal axis, the differentiation circuit is provided on a pre-stage of the current monitor circuit made up of the PMOS transistor 311, the NMOS transistors 312, 313 and the current source 342, to detect a current change, and the NMOS transistor 361 is turned on to deduct the monitor current Im4, whereby the detection of the current change (current extraction) due to the charged current of the parasitic capacity can be cancelled.

The current detection circuit 300 according to the above second and third embodiments can be provided with the information terminal 10 shown in FIG. 3, as in the current detection circuit 100 according to the above first embodiment.

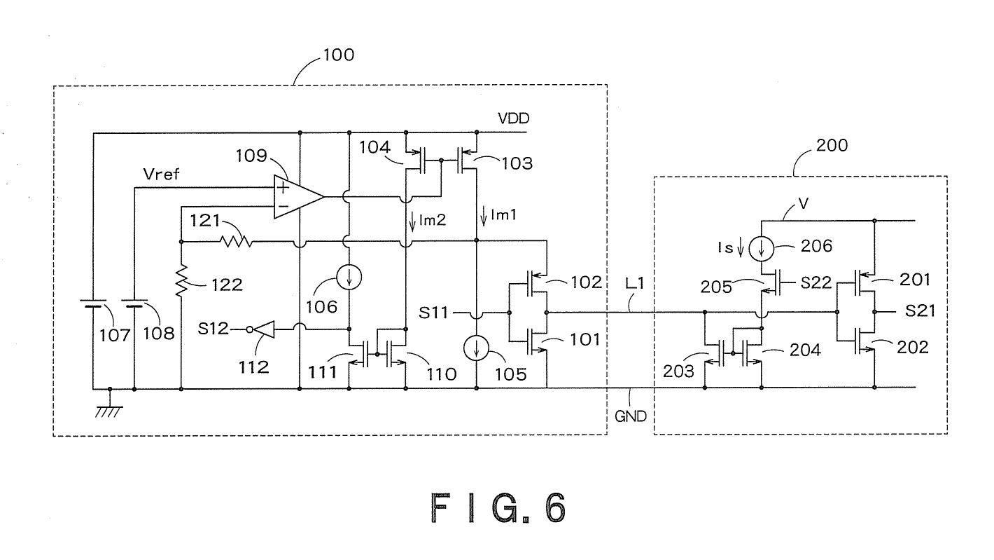

As shown in FIG. 6, a configuration may be formed in which the current detection circuit 100 according to the above first embodiment is added with resistors 121, 122, to provide a feedback resistor in the operational amplifier 109. One end of the resistor 121 is connected to the source electrode of the PMOS transistor 102 and the drain electrode of the PMOS transistor 103, and the other end thereof is connected to the inverting input terminal of the operational amplifier 109 and one end of the resistor 122. The other end of the resistor 122 is connected to the ground line GND. Providing such a feedback resistor can facilitate setting of the drain voltage of the PMOS transistor 103 (≈voltage of the input/output line L1) to a different voltage from the reference voltage (Vref) of the operational amplifier 109.

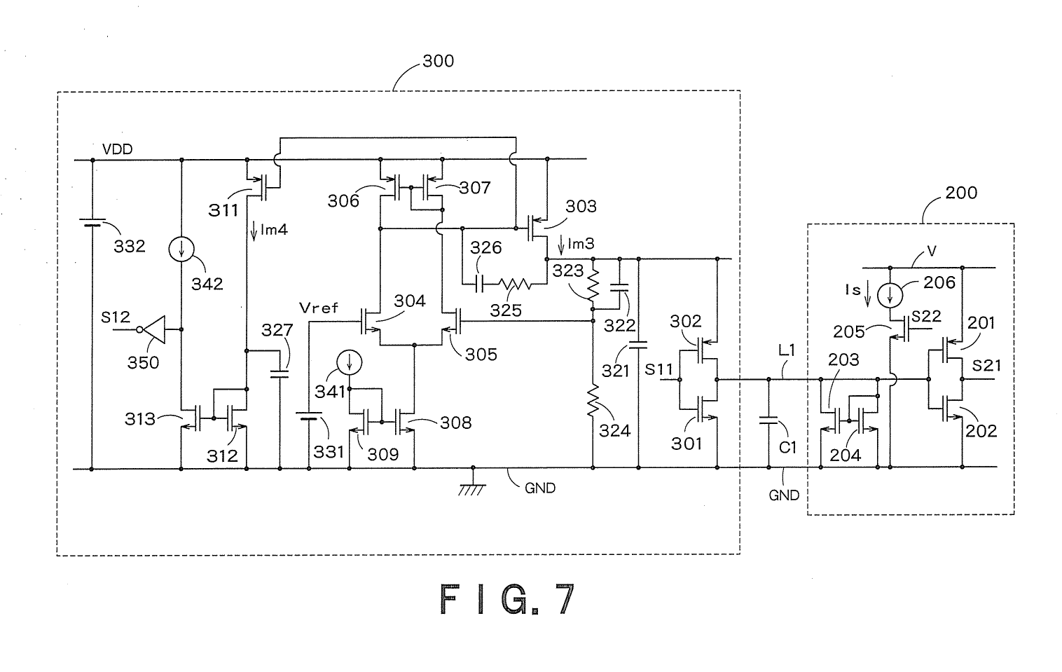

Further, as shown in FIG. 7, a configuration may be formed in which the NMOS transistor 310 is omitted from the current detection circuit 300 according to the above second embodiment. Forming such a configuration can facilitate setting of the drain voltage of the PMOS transistor 303 voltage of the input/output line L1) to a different voltage from the reference voltage (Vref) of the operational amplifier.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A current detection circuit, comprising:
a NMOS transistor, in which control signal is given to a gate electrode, whose source electrode is connected to a ground line, and whose drain electrode is connected to an input/output terminal;
a first PMOS transistor, in which the control signal is given to a gate electrode, and whose drain electrode is connected to the input/output terminal and the drain electrode of the NMOS transistor;
a second PMOS transistor, whose drain electrode is connected to the source electrode of the first PMOS transistor, and a first supply voltage is given to a source electrode; and
a detection section, which detects whether or not a current has changed at the input/output terminal from a change in current flowing through the second PMOS transistor.

2. The current detection circuit according to claim 1, further comprising:
a first current source, provided between a drain electrode of the second PMOS transistor and the ground line;
a third PMOS transistor, whose gate electrode is connected to a gate electrode of the second PMOS transistor, and in which the first supply voltage is given to a source electrode; and
an operational amplifier, in which a source voltage of the first PMOS transistor and a second supply voltage are input, and whose output terminal is connected to the gate electrode of the second PMOS transistor and the gate electrode of a third PMOS transistor,
wherein the detection section detects whether or not the current has changed at the input/output terminal, based on a change in drain current of the third PMOS transistor.

3. The current detection circuit according to claim 2, further comprising:
a first resistor, provided between an inverting input terminal of the operational amplifier and the source electrode of the first PMOS transistor; and
a second resistor, provided between the inverting input terminal of the operational amplifier and the ground line.

4. The current detection circuit according to claim 2, wherein the second PMOS transistor is larger in size than the third PMOS transistor.

5. The current detection circuit according to claim 2, wherein the detection section includes:
a second NMOS transistor, whose drain electrode and a gate electrode are connected to the drain electrode of the third PMOS transistor, and whose source electrode is connected to the ground line;
a third NMOS transistor, whose gate electrode is connected to the gate electrode and the drain electrode of the second NMOS transistor, and whose source electrode is connected to the ground line; and
a second current source, connected to a drain electrode of the third NMOS transistor.

6. The current detection circuit according to claim 2, wherein the detection section detects whether or not the current has changed during a period when the control signal is on low level.

7. The current detection circuit according to claim 1, further comprising:
first and second resistors, connected in series between the drain electrode of the second PMOS transistor and the ground line;
an operational amplifier, in which a second supply voltage and a voltage at a connection point of the first resistor and the second resistor are input, and whose output terminal is connected to the gate electrode of the second PMOS transistor; and
a capacitor, charged by a monitor current which flows through the detection section and whose current value changes associated with a change in current flowing through the second PMOS transistor,
wherein the detection section performs a comparison between the monitor current and a reference current, to detect whether or not the current has changed at the input/output terminal.

8. The current detection circuit according to claim 7, further comprising
a second NMOS transistor, which is provided between the drain electrode of the second PMOS transistor and the ground line, and whose gate electrode is connected to a first current source.

9. The current detection circuit according to claim 8, wherein
the detection section includes
a third PMOS transistor, in which the first supply voltage is given to a source electrode, and whose gate electrode is connected to the gate electrode of the second PMOS transistor,
a third NMOS transistor, whose drain electrode and gate electrode are connected to a drain electrode of the third PMOS transistor, and whose source electrode is connected to the ground line,
a fourth NMOS transistor, whose gate electrode is connected to the gate electrode and the drain electrode of the third NMOS transistor, and whose source electrode is connected to the ground line,
a second current source, connected to a drain electrode of the fourth NMOS transistor, and
the capacitor is provided between the drain electrode of the third PMOS transistor and the ground line.

10. The current detection circuit according to claim 9, wherein the detection section detects whether or not the current has changed at the input/output terminal during a period when the control signal is on low level.

11. The current detection circuit according to claim 1, further comprising:
a second NMOS transistor, which is provided between the drain electrode of the second PMOS transistor and the ground line, and whose gate electrode is connected to a first current source;
first and second resistors, connected in series between the drain electrode of the second PMOS transistor and the ground line;
an operational amplifier, in which a second supply voltage and a voltage at a connection point of the first resistor and the second resistor are input, and whose output terminal is connected to the gate electrode of the second PMOS transistor;
a current change detecting section, including a differentiation circuit that detects a change in current flowing through the second PMOS transistor; and
a transistor, in which a result of detection by the current change detecting section is given to a gate electrode, and which guides to the ground line a monitor current flowing through the detection section during the on-time and having a current value that changes associated with a change in current flowing through the second PMOS transistor,
wherein the detection section performs a comparison between the monitor current and a reference current, to detect whether or not the current has changed at the input/output terminal.

12. The current detection circuit according to claim 11, wherein
the detection section includes
a third PMOS transistor, in which the first supply voltage is given to a source electrode, and whose gate electrode is connected to the gate electrode of the second PMOS transistor,
a third NMOS transistor, whose drain electrode and a gate electrode are connected to a drain electrode of the third PMOS transistor, and whose source electrode is connected to the ground line,
a fourth NMOS transistor, whose gate electrode is connected to the gate electrode and the drain electrode of the third NMOS transistor, and whose source electrode is connected to the ground line,
a second current source, connected to a drain electrode of the fourth NMOS transistor, and
the transistor is provided between the drain electrode of the third PMOS transistor and the ground line.

13. The current detection circuit according to claim 12, wherein the detection section detects whether or not the current has changed at the input/output terminal during a period when the control signal is on low level.

14. An information terminal, comprising
the current detection circuit according to claim 1, which is connected to an IC card through the input/output terminal,
wherein data output from the IC card is obtained based on whether or not a current has changed at the input/output terminal, detected by the detection section, and communication is performed using the data.
